(19) United States
(12) Patent Application Publication
(10) Pub. No.: US 2026/0214929 A1
(43) Pub. Date: Jul. 23, 2026

(54) SEMICONDUCTOR DEVICE AND MANUFACTURING METHOD THEREOF

(71) Applicant: INNOSCIENCE (SUZHOU) SEMICONDUCTOR CO., LTD., Suzhou (CN)

(72) Inventors: Liang Song, Suzhou (CN); Fu Chen, Suzhou (CN); Jie Zhao, Suzhou (CN); Xingjie Huang, Suzhou (CN); Yan Liu, Suzhou (CN)

(21) Appl. No.: 19/425,106

(22) Filed: Dec. 18, 2025

Related U.S. Application Data
(63) Continuation of application No. PCT/CN2025/112115, filed on Aug. 1, 2025.

(30) Foreign Application Priority Data
Dec. 30, 2024 (CN) 202411959955.X
Jun. 27, 2025 (CN) 202510881234.X

(51) Int. Cl. H10D 30/47; H10D 30/01

(52) U.S. Cl. CPC H10D 30/475; H10D 30/015

(57) ABSTRACT

Provided are a semiconductor device and a manufacturing method thereof. The semiconductor device includes a substrate, a channel layer, and a barrier layer stacked in sequence; a barrier modulation; a sacrificial layer; a doped Group III-V semiconductor layer; and a gate. The barrier modulation layer is located on the side of the barrier layer facing away from the substrate and configured to protect the barrier layer and modulate an energy band. The sacrificial layer is located on the side of the barrier modulation layer facing away from the substrate and configured to protect the barrier modulation layer. The doped Group III-V semiconductor layer is located on the side of the sacrificial layer facing away from the substrate. The gate is located on the side of the doped Group III-V semiconductor layer facing away from the substrate.

### CROSS-REFERENCE TO RELATED APPLICATIONS

This is a continuation of International Patent Application No. PCT/CN2025/112115, filed Aug. 1, 2025, which claims priority to Chinese Patent Application No. 202411959955.X filed with the China National Intellectual Property Administration (CNIPA) on Dec. 30, 2024 and Chinese Patent Application No. 202510881234.X filed with the CNIPA on Jun. 27, 2025, the disclosures of which are incorporated herein by reference in their entireties.

### TECHNICAL FIELD

The present application relates to the field of semiconductor technology and, in particular to, a semiconductor device and a manufacturing method thereof.

### BACKGROUND

Semiconductor devices such as enhancement-mode high-electron-mobility transistors (HEMTs) play a significant role in the field of modern electronic technology.

In a gallium nitride (GaN) semiconductor device, typically a barrier layer and a channel layer form a two-dimensional electron gas (2DEG) to form a conductive channel. However, in the related art, a GaN semiconductor device exhibits a low 2DEG concentration and is required to have an improved performance.

### SUMMARY

The present application provides a semiconductor device and a manufacturing method thereof to improve the electrical performance of the semiconductor device.

The present application provides a semiconductor device. The semiconductor device includes a substrate, a channel layer, and a barrier layer stacked in sequence; a barrier modulation; a sacrificial layer; a doped Group III-V semiconductor layer; and a gate.

The barrier modulation layer is located on the side of the barrier layer facing away from the substrate and configured to protect the barrier layer and modulate an energy band. The thickness of the barrier modulation layer is less than the thickness of the barrier layer.

The sacrificial layer is located on the side of the barrier modulation layer facing away from the substrate and configured to protect the barrier modulation layer.

The doped Group III-V semiconductor layer is located on the side of the sacrificial layer facing away from the substrate. The orthographic projection of the doped Group III-V semiconductor layer on the substrate covers the orthographic projection of the sacrificial layer on the substrate.

The gate is located on the side of the doped Group III-V semiconductor layer facing away from the substrate.

In one or more examples, the semiconductor device further includes a source located on the side of the barrier layer facing away from the substrate, and a drain located on the side of the barrier layer facing away from the substrate.

The orthographic projection of the gate on the substrate is located between the orthographic projection of the source on the substrate and the orthographic projection of the drain on the substrate.

In one or more examples, the barrier modulation layer entirely covers the barrier layer, the source is located on the side of the barrier modulation layer facing away from the substrate, and the drain is located on the side of the barrier modulation layer facing away from the substrate.

Alternatively, the barrier modulation layer exposes a portion of the barrier layer corresponding to the source and a portion of the barrier layer corresponding to the drain, the source is in contact with the barrier layer, and the drain is in contact with the barrier layer.

In one or more examples, the semiconductor device also includes a passivation layer. The passivation layer covers the gate and the barrier modulation layer exposed by the sacrificial layer.

In one or more examples, the thickness of the barrier modulation layer is less than a quarter of the thickness of the barrier layer.

In one or more examples, the thickness of the barrier modulation layer is less than the thickness of the sacrificial layer, and the thickness of the sacrificial layer is less than the thickness of the barrier layer.

In one or more examples, the thickness of the barrier modulation layer ranges from 0.3 nm to 1.5 nm, and/or the thickness of the sacrificial layer ranges from 1 nm to 5 nm.

In one or more examples, the thickness of the Group III-V semiconductor layer is greater than or equal to 100 nm, and/or the thickness of the barrier layer ranges from 8 nm to 15 nm.

In one or more examples, the etch rate of the sacrificial layer is greater than the etch rate of the doped Group III-V semiconductor layer and less than the etch rate of the barrier modulation layer.

In one or more examples, the material of the barrier modulation layer includes AlₓGa₁₋ₓN, and the Al composition in the barrier modulation layer is greater than the Al composition in the barrier layer, where x>0.5.

In one or more examples, the material of the sacrificial layer includes AlGaN, and/or the material of the doped Group III-V semiconductor layer includes p-type doped GaN.

The present application provides a manufacturing method of a semiconductor device. The manufacturing method is used for manufacturing the preceding semiconductor device. The manufacturing method includes providing the substrate; forming the channel layer, the barrier layer, the barrier modulation layer, a sacrificial material layer, and a doped Group III-V material semiconductor layer stacked in sequence on the substrate; and etching the doped Group III-V material semiconductor layer and the sacrificial material layer to form the doped Group III-V semiconductor layer and the sacrificial layer, respectively.

According to solutions of examples of the present application, the semiconductor device includes a substrate, a channel layer, and a barrier layer stacked in sequence; a barrier modulation; a sacrificial layer; a doped Group III-V semiconductor layer; and a gate. The barrier modulation layer is located on the side of the barrier layer facing away from the substrate and configured to protect the barrier layer and modulate an energy band. The thickness of the barrier modulation layer is less than the thickness of the barrier layer. The sacrificial layer is located on the side of the barrier modulation layer facing away from the substrate and configured to protect the barrier modulation layer. The doped Group III-V semiconductor layer is located on the side of the sacrificial layer facing away from the substrate. The orthographic projection of the doped Group III-V semiconductor layer on the substrate covers the orthographic projection of the sacrificial layer on the substrate. The gate is located on the side of the doped Group III-V semiconductor layer facing away from the substrate. The relatively thin barrier modulation layer can not only increase the 2DEG concentration of the semiconductor device but also ensure the formation of an enhancement-mode device. Moreover, the sacrificial layer can ensure that the relatively thin barrier modulation layer is not completely etched away during the etching process, thereby ensuring that the semiconductor device exhibits a high 2DEG concentration.

It is to be understood that the content described in this part is neither intended to identify key or important features of the examples of the present application nor intended to limit the scope of the present application. Other features of the present application are apparent from the description provided hereinafter.

### BRIEF DESCRIPTION OF DRAWINGS

To illustrate technical solutions in examples of the present application more clearly, drawings used in the description of the examples are briefly described below. Apparently, the drawings described below illustrate part of the examples of the present application. Those of ordinary skill in the art may further obtain other drawings based on these drawings on the premise that no creative work is done.

FIG. 1 is a diagram illustrating the structure of a semiconductor device according to examples of the present application.

FIG. 2 is another diagram illustrating the structure of a semiconductor device according to examples of the present application.

FIG. 3 is another diagram illustrating the structure of a semiconductor device according to examples of the present application.

FIG. 4 is a flowchart of a manufacturing method of a semiconductor device according to examples of the present application.

FIG. 5 and FIG. 6 are each a diagram illustrating the structure of a product formed using steps of a manufacturing method of a semiconductor device according to examples of the present application.

### DETAILED DESCRIPTION

For a better understanding of the solution of the present application by those skilled in the art, the technical solutions in examples of the present application are described clearly and completely hereinafter in conjunction with the drawings in the examples of the present application. Apparently, the examples described hereinafter are part, not all, of examples of the present application. Based on the examples of the present application, all other examples obtained by those of ordinary skill in the art on the premise that no creative work is done are within the scope of the present application.

It is to be noted that the terms “first”, “second”, and the like in the description, claims, and drawings of the present application are used for distinguishing between similar objects and are not necessarily used for describing a particular order or sequence. It is to be understood that data used in this manner are interchangeable where appropriate so that the examples of the present application described herein can be implemented in an order not illustrated or described herein. In addition, the terms “include”, “have”, and any variations thereof are intended to encompass a non-exclusive inclusion. For example, a process, method, system, product, or device that includes a series of steps or units not only includes the expressly listed steps or units but may also include other steps or units that are not expressly listed or are inherent to such process, method, product, or device.

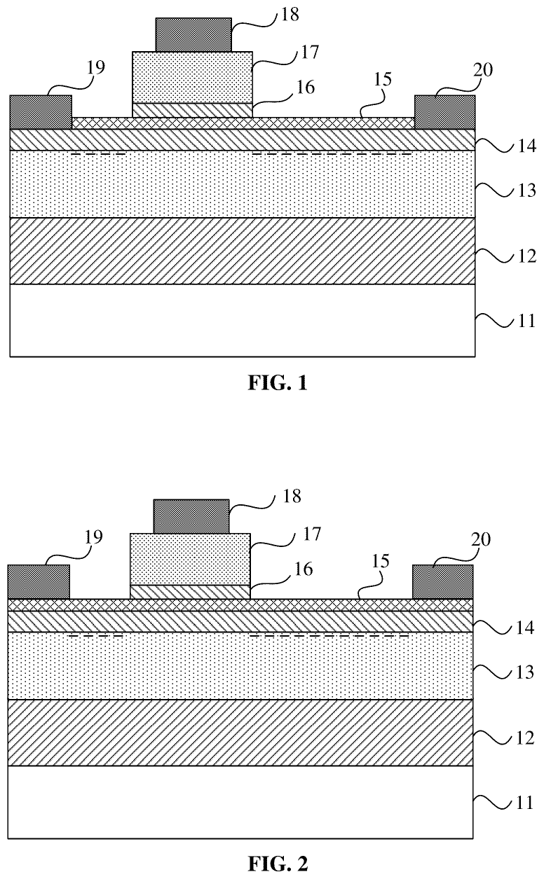

FIG. 1 is a diagram illustrating the structure of a semiconductor device according to examples of the present application. Referring to FIG. 1, the semiconductor device includes a substrate 11, a channel layer 13, and a barrier layer 14 stacked in sequence; a barrier modulation layer 15; a sacrificial layer 16; a doped Group III-V semiconductor layer 17; and a gate 18. The barrier modulation layer 15 is located on the side of the barrier layer 14 facing away from the substrate 11 and configured to protect the barrier layer 14 and modulate an energy band. The thickness of the barrier modulation layer 15 is less than the thickness of the barrier layer 14. The sacrificial layer 16 is located on the side of the barrier modulation layer 15 facing away from the substrate 11 and configured to protect the barrier modulation layer 15. The doped Group III-V semiconductor layer 17 is located on the side of the sacrificial layer 16 facing away from the substrate 11. The orthographic projection of the doped Group III-V semiconductor layer 17 on the substrate 11 covers the orthographic projection of the sacrificial layer 16 on the substrate 11. The gate 18 is located on the side of the doped Group III-V semiconductor layer 17 facing away from the substrate 11.

The semiconductor device of this example may be an enhancement-mode HEMT. The substrate 11 serves to support the semiconductor device and to provide insulation. The substrate 11 may be, for example, a silicon carbide substrate, a silicon substrate, a sapphire substrate, a diamond substrate, or a silicon nitride substrate. The channel layer 13 and the barrier layer 14 form a heterojunction. A 2DEG is formed at the interface between the channel layer 13 and the barrier layer 14 to generate a conductive channel. The doped Group III-V semiconductor layer 17 is located between the gate 18 and the barrier layer 14 of the semiconductor device. The doped Group III-V semiconductor layer 17 may deplete the 2DEG below the gate 18 so that the semiconductor device presents a normally-off characteristic. When a suitable bias voltage is applied between the gate and the source of the semiconductor device, the conductive channel is reformed so that the semiconductor device is turned on. The performance of the barrier layer 14 has a significant impact on the 2DEG concentration. The polarization intensity of the barrier modulation layer 15 is much greater than that of the barrier layer 14. Therefore, the barrier modulation layer 15 of the semiconductor device increases the 2DEG concentration. However, since the ability of the doped Group III-V semiconductor layer 17 to deplete the 2DEG is limited, it becomes more difficult for the semiconductor device to achieve the enhancement mode after the barrier modulation layer 15 is added.

In addition, for regions (for example, a corresponding region between the gate and the source and a corresponding region between the gate and the drain) in which a 2DEG is required to be generated in the off state, the barrier modulation layer 15 is disposed. The barrier modulation layer 15 modulates the energy band to increase the 2DEG concentration, thereby reducing the resistance of the semiconductor device. That is, the semiconductor device requires not only a higher 2DEG concentration but also the enhancement mode. In this example, the thickness of the barrier modulation layer 15 is limited. That is, the thickness of the barrier modulation layer 15 is set to be less than the thickness of the barrier layer 14. The small thickness of the barrier modulation layer 15 not only increases the 2DEG concentration but also avoids the failure to achieve enhancement mode due to an excessively high 2DEG concentration. In addition, the stress of the barrier modulation layer 15 is high. If the barrier modulation layer 15 is too thick during the growth process, the lattice stress is large or even relaxed, thereby affecting the performance of the barrier layer 14. In this example, the thickness of the barrier modulation layer 15 is set to be relatively thin. This can prevent the stress of the barrier modulation layer 15 during the growth process from affecting the barrier layer 14.

In the semiconductor device, the thickness of the barrier layer 14 is also relatively thin. In this example, the thickness of the barrier modulation layer 15 is set to be even thinner, whereas, by comparison, the doped Group III-V semiconductor layer 17 has a relatively large thickness. Therefore, in the process of etching the doped Group III-V semiconductor layer, if the doped Group III-V semiconductor layer is over-etched, the risk that the barrier modulation layer 15 is over-etched and completely removed is also large. Therefore, in this example, the sacrificial layer 16 is further disposed. The etch rate of the sacrificial layer 16 is greater than the etch rate of the doped Group III-V semiconductor layer and less than the etch rate of the barrier modulation layer 15. The polarization intensity of the sacrificial layer 16 is less than the polarization intensity of the barrier modulation layer 15. For example, the sacrificial layer 16 is defined as being formed by etching a sacrificial material layer, and the doped Group III-V semiconductor layer 17 is defined as being formed by etching a doped Group III-V material semiconductor layer. If over-etching is performed when the doped Group III-V material semiconductor layer is etched, the sacrificial material layer is etched first, thereby protecting the subsequent barrier modulation layer 15 and preventing the excessively thin barrier modulation layer 15 from being etched.

According to the solution of this example, the semiconductor device includes a substrate, a channel layer, and a barrier layer stacked in sequence; a barrier modulation; a sacrificial layer; a doped Group III-V semiconductor layer; and a gate. The barrier modulation layer is located on the side of the barrier layer facing away from the substrate and configured to protect the barrier layer and modulate an energy band. The thickness of the barrier modulation layer is less than the thickness of the barrier layer. The sacrificial layer is located on the side of the barrier modulation layer facing away from the substrate and configured to protect the barrier modulation layer. The doped Group III-V semiconductor layer is located on the side of the sacrificial layer facing away from the substrate. The orthographic projection of the doped Group III-V semiconductor layer on the substrate covers the orthographic projection of the sacrificial layer on the substrate. The gate is located on the side of the doped Group III-V semiconductor layer facing away from the substrate. The relatively thin barrier modulation layer can not only increase the 2DEG concentration of the semiconductor device but also ensure the formation of an enhancement-mode device. Moreover, the sacrificial layer can ensure that the relatively thin barrier modulation layer is not completely etched away during the etching process, thereby ensuring that the semiconductor device exhibits a high 2DEG concentration.

In one or more examples, with continued reference to FIG. 1, the semiconductor device further includes a source 19 located on the side of the barrier layer 14 facing away from the substrate 11 and a drain 20 located on the side of the barrier layer facing away from the substrate 11. The orthographic projection of the gate 18 on the substrate 11 is located between the orthographic projection of the source 19 on the substrate 11 and the orthographic projection of the drain 20 on the substrate 11.

An ohmic contact may be formed between the gate 18 and the doped Group III-V semiconductor layer 17; an ohmic contact may be formed between the source 19 and the barrier layer 14; and an ohmic contact may be formed between the drain 20 and the barrier layer 14. In the off state, the 2DEG below the gate 18 is depleted by the doped Group III-V semiconductor layer 17 so that the conductive channel between the source 19 and the drain 20 is blocked. In the on state, that is, when a suitable bias voltage is applied between the gate 18 and the source 19, the conductive channel below the gate 18 is reformed so that current can be transmitted between the source 19 and the drain 20. The source 19 may be one of or an alloy of titanium and aluminum. The drain 20 may be one of or an alloy of titanium and aluminum. The gate 18 may be one of or an alloy of nickel and gold.

In one or more examples, with continued reference to FIG. 1, the semiconductor device further includes a buffer layer 12 located between the substrate 11 and the channel layer 13. The buffer layer 12 can alleviate the problem of lattice mismatch between the substrate 11 and the channel layer 13. In some examples, the buffer layer 12 may be, for example, a GaN layer. The channel layer 13 may be one or more of a GaN layer, an AlGaN layer, and an InGaN layer. The doped Group III-V semiconductor layer 17 is, for example, a p-type doped GaN layer.

In one or more examples, with continued reference to FIG. 1, in some examples, the barrier modulation layer 15 expose a portion of the barrier layer 14 corresponding to the source 19 and a portion of the barrier layer 14 corresponding to the drain 20, the source 19 is in contact with the barrier layer 14, and the drain 20 is in contact with the barrier layer 14.

In this example, the barrier modulation layer 15 covers the portion of the barrier layer 14 corresponding to the doped Group III-V semiconductor layer 17, the portion of the barrier layer 14 corresponding to the region between the doped Group III-V semiconductor layer 17 and the source 19, and the portion of the barrier layer 14 corresponding to the region between the doped Group III-V semiconductor layer 17 and the drain 20.

In one or more examples, as shown in FIG. 2, FIG. 2 is another diagram illustrating the structure of a semiconductor device according to examples of the present application. In this example, the barrier modulation layer 15 entirely covers the barrier layer 14, the source 19 is located on the side of the barrier modulation layer 15 facing away from the substrate 11, and the drain 20 is located on the side of the barrier modulation layer 15 facing away from the substrate 11.

In this example, the barrier modulation layer 15 entirely covers the barrier layer 14, the bottom surface of the source 19 is in contact with the barrier modulation layer 15, and the bottom surface of the drain 20 is also in contact with the barrier modulation layer 15. There is no need to etch the barrier modulation layer. This can avoid affecting the interface morphology and thickness of the barrier layer 14 due to over-etching of the region of the barrier layer 14 between the gate 18 and the source 19 when the barrier modulation layer 15 is etched. This can also avoid affecting the interface morphology and thickness of the barrier layer 14 due to over-etching of the area of the barrier layer 14 between the gate 18 and the drain 20 when the barrier modulation layer 15 is etched.

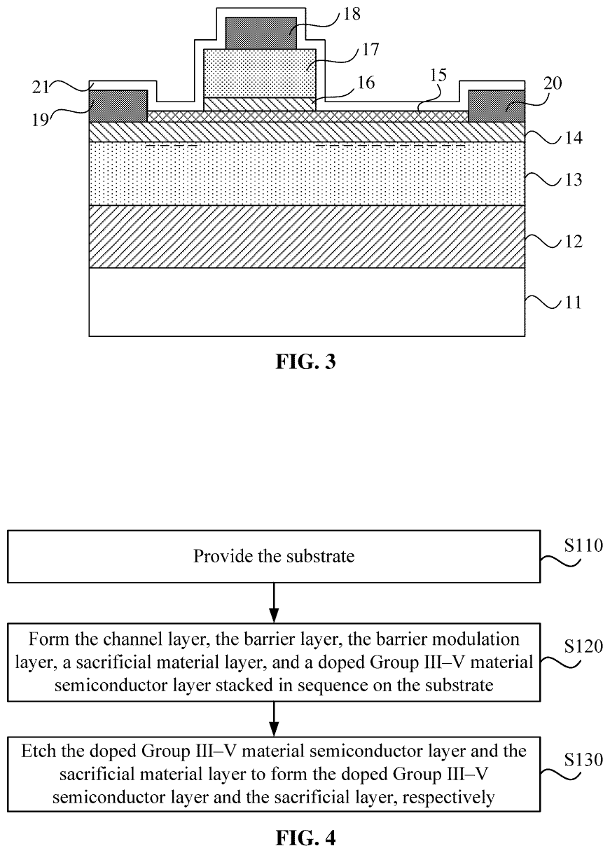

In one or more examples, FIG. 3 is another diagram illustrating the structure of a semiconductor device according to examples of the present application. Referring to FIG. 3, the semiconductor device also includes a passivation layer 21. The passivation layer 21 covers the gate 18 and covers the barrier modulation layer 15 exposed by the sacrificial layer 16.

In this example, since the barrier modulation layer 15 is not completely etched, and during the formation of the sacrificial layer 16, the portions of the sacrificial material layer other than the sacrificial layer 16 are all etched. That is, the barrier modulation layer 15 is in contact with the passivation layer 21. In some examples, the barrier modulation layer 15 and the passivation layer 21 are made of the same material at their contact surface. For example, when both layers are AlN, an AlN—AlN interface is formed, resulting in a high-quality interface. In the related art, the barrier layer 14 is in contact with the passivation layer 21, the barrier layer 14 is generally AlGaN, and the passivation layer 21 is generally AlN, forming an AlGaN—AlN interface. During the etching of AlGaN, the nitrogen in AlGaN is selectively etched, and dangling bonds are easily formed on the Ga surface. When exposed to air, the surface is readily oxidized to form G-O bonds. That is, in the related art, the surface at the interface between the barrier layer 14 and the passivation layer 21 contains a large number of Ga—O bonds, resulting in many interface defects. In some other examples, the material of the barrier modulation layer 15 includes AlₓGa₁₋ₓN, where x>0.5, and the Al composition in the barrier modulation layer 15 is greater than the Al composition in the barrier layer 14. That is, the barrier modulation layer 15 uses high-Al-composition AlGaN. AIN or high-Al-composition AlGaN has a wide bandgap of the energy band that helps modulate the energy band. This effectively prevents the 2DEG in the channel from moving to the surface of the barrier modulation layer 15 facing away from the substrate 11 and thus prevents the 2DEG in the channel from being trapped by surface defects. That is, the configuration of this example allows the barrier modulation layer 15 to increase the 2DEG concentration in the channel. Moreover, when the size of the barrier modulation layer 15 is fixed, a higher Al composition corresponds to a lower Ga composition. As a result, fewer Ga—O bonds are present at the interface between the barrier modulation layer 15 and the passivation layer 21. This also helps optimize the interface quality between the barrier modulation layer 15 and the passivation layer 21. In summary, the barrier modulation layer 15 of this example not only modulates the energy band but also, when the semiconductor device includes a passivation layer, helps optimize the interface between the barrier modulation layer 15 and the passivation layer 21.

In one or more examples, the thickness of the barrier modulation layer 15 is less than a quarter of the thickness of the barrier layer 14.

If the thickness of the barrier modulation layer 15 is too large, the 2DEG concentration becomes excessive, making it more difficult to form an enhancement-mode device. In the configuration of this example, the barrier modulation layer 15 is much thinner than the barrier layer 14. The barrier modulation layer 15 may enhance the 2DEG concentration without causing the 2DEG concentration to become excessive. In addition, the barrier modulation layer 15 is much thinner than the barrier layer 14. The barrier modulation layer 15 may affect the performance of the barrier layer 14 during growth due to high stress. In one or more examples, the thickness of the barrier modulation layer 15 may be, for example, one-sixth, one-seventh, or one-eighth of the thickness of the barrier layer 14.

In one or more examples, the thickness of the barrier modulation layer 15 is less than the thickness of the sacrificial layer 16, and the thickness of the sacrificial layer 16 is less than the thickness of the barrier layer 14.

The thickness of the sacrificial layer 16 is greater than that of the barrier modulation layer 15. This ensures that during the etching of the doped Group III-V semiconductor layer 17, the barrier modulation layer 15 is not etched away. Moreover, the thickness of the sacrificial layer 16 is less than that of the barrier layer 14 so that the sacrificial layer 16 has little effect on the 2DEG concentration, avoiding an excessive 2DEG concentration by the sacrificial layer 16 that would make it difficult to form an enhancement-mode device.

In one or more examples, the sum of the thicknesses of the sacrificial layer 16 and the thicknesses of the barrier modulation layer 15 is less than the thickness of the barrier layer 14. The sacrificial layer 16 and the barrier modulation layer 15 are relatively thin overall. This facilitates the migration of holes from the doped Group III-V semiconductor layer 17 into the barrier layer 14 to deplete the 2DEG, thereby promoting the formation of an enhancement-mode device.

In one or more examples, the thickness of the barrier modulation layer 15 ranges from 0.3 nm to 1.5 nm. In one or more examples, the thickness of the barrier modulation layer 15 may be, for example, 0.3 nm, 0.5 nm, 0.7 nm, 0.9 nm, 1.1 nm, 1.3 nm, or 1.5 nm.

In one or more examples, the thickness of the sacrificial layer 16 ranges from 1 nm to 5 nm. In one or more examples, the thickness of the sacrificial layer 16 may be, for example, 1 nm, 2 nm, 3 nm, 4 nm, or 5 nm.

In one or more examples, the thickness of the barrier layer 14 ranges from 8 nm to 15 nm. In one or more examples, the thickness of the barrier layer 14 may be, for example, 8 nm, 9 nm, 10 nm, 11 nm, 12 nm, 13 nm, 14 nm, or 15 nm.

In one or more examples, the etch rate of the sacrificial layer 16 is greater than the etch rate of the doped Group III-V semiconductor layer, and the etch rate of the sacrificial layer 16 is less than the etch rate of the barrier modulation layer 15 in etching the doped Group III-V material semiconductor layer.

Because the etch rate of the sacrificial material layer is less than that of the doped Group III-V material semiconductor layer, during the etching of the doped Group III-V material semiconductor layer, the doped Group III-V material semiconductor layer is first etched at a higher rate to form the doped Group III-V semiconductor layer 17. When the etching reaches the sacrificial material layer, the etch rate slows down but is still higher than the etch rate of the barrier modulation layer 15. Therefore, the etch rate is slowed to prevent the barrier modulation layer 15 from being completely etched while avoiding an excessively slow etch rate that would fail to remove the sacrificial material layer 16 to expose the corresponding portion of the barrier modulation layer. That is, the configuration of this example can ensure that even when the barrier modulation layer 15 is relatively thin, during the etching of the doped Group III-V material semiconductor layer, the etching stops at a position at the barrier modulation layer 15.

In some examples, the etch rate of the barrier modulation layer 15 is less than the etch rate of the doped Group III-V material semiconductor layer, and the barrier modulation layer 15 may also serve as an etch stop structure for the doped Group III-V material semiconductor layer. In other words, the combined structure of the sacrificial layer 16 and the barrier modulation layer 15 may be understood as an etch stop layer of the doped Group III-V semiconductor layer. The barrier modulation layer 15 has a relatively high polarization strength, thereby increasing the 2DEG concentration. The sacrificial layer 16 increases the overall thickness of the etch stop layer but does not significantly increase the 2DEG concentration like the barrier modulation layer 15. Therefore, this may be understood as that the sacrificial layer equivalently increases the thickness of the barrier modulation layer 15 on the basis of the barrier modulation layer 15 and does not increase the ability of the barrier modulation layer 15 to increase the 2DEG concentration. Thus, during the etching of the doped Group III-V material semiconductor layer, the barrier modulation layer 15 is not completely etched.

In one or more examples, the etching gas for etching the doped Group III-V material semiconductor layer may include a chlorine-based etching gas doped with oxygen (O) or fluorine (F).

Aluminum in the barrier modulation layer 15 reacts with oxygen (O) in the etching gas to form dense and non-volatile Al₂O3, and aluminum in the barrier modulation layer 15 reacts with fluorine (F) in the etching gas to form dense and non-volatile AlF₃. As a result, the etch rate of the etching gas for the doped Group III-V semiconductor layer 17 and the sacrificial layer 16 is higher than that for the barrier modulation layer 15.

In one or more examples, the thickness of the doped Group III-V semiconductor layer 17 may be greater than or equal to 100 nm.

In one or more examples, the sacrificial layer 16 may be a p-type doped semiconductor material layer. For example, the sacrificial layer 16 may be a p-type InN. In this example, the sacrificial layer 16 can not only protect the barrier modulation layer 15 but also consume the increased 2DEG concentration caused by the presence of the barrier modulation layer 15. As a result, the doped Group III-V semiconductor layer 17 can deplete the 2DEG below the gate, thereby forming an enhancement-mode device.

In one or more examples, the material of the sacrificial layer 16 may be AlGaN.

Based on the same application concept, the present application also provides a manufacturing method of a semiconductor device. As shown in FIG. 4, FIG. 4 is a flowchart of a manufacturing method of a semiconductor device according to examples of the present application. The manufacturing method of a semiconductor device is used to manufacture the semiconductor device of any example of the present application. The manufacturing method of a semiconductor device includes steps S110 to S130 below.

In step S110, the substrate is provided.

In step S120, the channel layer, the barrier layer, the barrier modulation layer, a sacrificial material layer, and a doped Group III-V material semiconductor layer stacked in sequence on the substrate are formed.

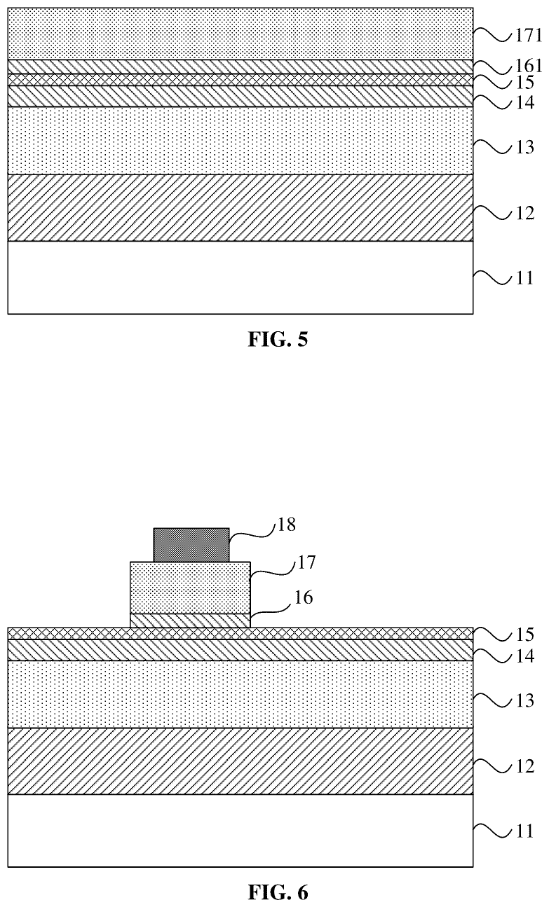

FIG. 5 and FIG. 6 are each a diagram illustrating the structure of a product formed using steps of a manufacturing method of a semiconductor device according to examples of the present application. As shown in FIG. 5, a buffer layer 12, the channel layer 13, the barrier layer 14, the barrier modulation layer 15, the sacrificial material layer 161, and the doped Group III-V material semiconductor layer 171 may be first epitaxially formed on the substrate 11. The sacrificial material layer 161 is subsequently used to form the sacrificial layer. The doped Group III-V material semiconductor layer is subsequently used to form the doped Group III-V semiconductor layer.

In step S130, the doped Group III-V material semiconductor layer and the sacrificial material layer are etched to form the doped Group III-V semiconductor layer and the sacrificial layer, respectively.

As shown in FIG. 6, the doped Group III-V material semiconductor layer 171 may be etched using an etching gas including a chlorine-based etching gas doped with oxygen (O) or fluorine (F). In addition, the gate 18 may also be used as a mask so that the portion of the doped Group III-V material semiconductor layer 171 below the gate 18 is retained, that is, the doped Group III-V semiconductor layer 17 is retained. The doped Group III-V material semiconductor layer 171 is much thicker than the sacrificial material layer 161. During etching, over-etching may reach the sacrificial material layer 161. Setting the etch rate of the sacrificial material layer to be less than that of the barrier modulation layer 15 ensures that the etching stops at the barrier modulation layer 15. The relatively thin barrier modulation layer can not only increase the 2DEG concentration of the semiconductor device but also ensure the formation of an enhancement-mode device. Moreover, the sacrificial layer can ensure that the relatively thin barrier modulation layer is not completely etched away during the etching process, thereby ensuring that the semiconductor device exhibits a high 2DEG concentration.

It is to be understood that the source and the drain may be formed subsequently, thereby forming the semiconductor device shown in FIG. 2.

It is to be understood that various forms of the preceding flows may be used with steps reordered, added, or deleted. For example, the steps described in the present application may be executed in parallel, in sequence, or in a different order, as long as the desired results of the technical solutions of the present application can be achieved. The execution sequence of the steps is not limited herein.

The preceding examples are not intended to limit the scope of the present application. It is to be understood by those skilled in the art that various modifications, combinations, subcombinations, and substitutions may be made according to design requirements and other factors. Any modifications, equivalent substitutions, and improvements that are made within the spirit and principle of the present application are within the scope of the present application.

What is claimed is:

1. A semiconductor device, comprising:
a substrate, a channel layer, and a barrier layer stacked in sequence;
a barrier modulation layer located on a side of the barrier layer facing away from the substrate and configured to protect the barrier layer and modulate an energy band, wherein a thickness of the barrier modulation layer is less than a thickness of the barrier layer;
a sacrificial layer located on a side of the barrier modulation layer facing away from the substrate and configured to protect the barrier modulation layer;
a doped Group III-V semiconductor layer located on a side of the sacrificial layer facing away from the substrate, wherein an orthographic projection of the doped Group III-V semiconductor layer on the substrate covers an orthographic projection of the sacrificial layer on the substrate; and
a gate located on a side of the doped Group III-V semiconductor layer facing away from the substrate.

2. The semiconductor device of claim 1, further comprising:
a source located on the side of the barrier layer facing away from the substrate; and
a drain located on the side of the barrier layer facing away from the substrate;
wherein an orthographic projection of the gate on the substrate is located between an orthographic projection of the source on the substrate and an orthographic projection of the drain on the substrate.

3. The semiconductor device of claim 2, wherein:
the barrier modulation layer entirely covers the barrier layer, the source is located on the side of the barrier modulation layer facing away from the substrate, and the drain is located on the side of the barrier modulation layer facing away from the substrate; or
the barrier modulation layer exposes a portion of the barrier layer corresponding to the source and a portion of the barrier layer corresponding to the drain, the source is in contact with the barrier layer, and the drain is in contact with the barrier layer.

4. The semiconductor device of claim 1, further comprising a passivation layer, wherein the passivation layer covers the gate and covers the barrier modulation layer exposed by the sacrificial layer.

5. The semiconductor device of claim 1, wherein the thickness of the barrier modulation layer is less than a quarter of the thickness of the barrier layer.

6. The semiconductor device of claim 1, wherein the thickness of the barrier modulation layer is less than a thickness of the sacrificial layer, and the thickness of the sacrificial layer is less than the thickness of the barrier layer.

7. The semiconductor device of claim 5, wherein the semiconductor device satisfies at least one of the following:
the thickness of the barrier modulation layer ranges from 0.3 nm to 1.5 nm; or
a thickness of the sacrificial layer ranges from 1 nm to 5 nm.

8. The semiconductor device of claim 6, wherein the semiconductor device satisfies at least one of the following:
the thickness of the barrier modulation layer ranges from 0.3 nm to 1.5 nm; or
a thickness of the sacrificial layer ranges from 1 nm to 5 nm.

9. The semiconductor device of claim 1, wherein a thickness of the doped Group III-V semiconductor layer is greater than or equal to 100 nm, and/or the thickness of the barrier layer ranges from 8 nm to 15 nm.

10. The semiconductor device of claim 1, wherein an etch rate of the sacrificial layer is greater than an etch rate of the doped Group III-V semiconductor layer and less than an etch rate of the barrier modulation layer.

11. The semiconductor device of claim 1, wherein:
a material of the barrier modulation layer comprises AlN; or
a material of the barrier modulation layer comprises AlₓGa₁₋ₓN, and an Al composition in the barrier modulation layer is greater than an Al composition in the barrier layer, wherein x>0.5.

12. The semiconductor device of claim 1, wherein the semiconductor device satisfies at least one of the following:
a material of the sacrificial layer comprises AlGaN;
a material of the doped Group III-V semiconductor layer comprises p-type doped GaN.

13. A manufacturing method of a semiconductor device, for manufacturing the semiconductor device of claim 1, comprising:
providing the substrate;
forming the channel layer, the barrier layer, the barrier modulation layer, a sacrificial material layer, and a doped Group III-V material semiconductor layer stacked in sequence on the substrate; and
etching the doped Group III-V material semiconductor layer and the sacrificial material layer to form the doped Group III-V semiconductor layer and the sacrificial layer, respectively.

14. A manufacturing method of a semiconductor device, for manufacturing the semiconductor device of claim 2, comprising:
providing the substrate;
forming the channel layer, the barrier layer, the barrier modulation layer, a sacrificial material layer, and a doped Group III-V material semiconductor layer stacked in sequence on the substrate; and
etching the doped Group III-V material semiconductor layer and the sacrificial material layer to form the doped Group III-V semiconductor layer and the sacrificial layer, respectively.

15. A manufacturing method of a semiconductor device, for manufacturing the semiconductor device of claim 3, comprising:
providing the substrate;
forming the channel layer, the barrier layer, the barrier modulation layer, a sacrificial material layer, and a doped Group III-V material semiconductor layer stacked in sequence on the substrate; and
etching the doped Group III-V material semiconductor layer and the sacrificial material layer to form the doped Group III-V semiconductor layer and the sacrificial layer, respectively.

16. A manufacturing method of a semiconductor device, for manufacturing the semiconductor device of claim 4, comprising:
providing the substrate;
forming the channel layer, the barrier layer, the barrier modulation layer, a sacrificial material layer, and a doped Group III-V material semiconductor layer stacked in sequence on the substrate; and
etching the doped Group III-V material semiconductor layer and the sacrificial material layer to form the doped Group III-V semiconductor layer and the sacrificial layer, respectively.

17. A manufacturing method of a semiconductor device, for manufacturing the semiconductor device of claim 5, comprising:
providing the substrate;
forming the channel layer, the barrier layer, the barrier modulation layer, a sacrificial material layer, and a doped Group III-V material semiconductor layer stacked in sequence on the substrate; and
etching the doped Group III-V material semiconductor layer and the sacrificial material layer to form the doped Group III-V semiconductor layer and the sacrificial layer, respectively.

18. A manufacturing method of a semiconductor device, for manufacturing the semiconductor device of claim 6, comprising:
providing the substrate;
forming the channel layer, the barrier layer, the barrier modulation layer, a sacrificial material layer, and a doped Group III-V material semiconductor layer stacked in sequence on the substrate; and
etching the doped Group III-V material semiconductor layer and the sacrificial material layer to form the doped Group III-V semiconductor layer and the sacrificial layer, respectively.

19. A manufacturing method of a semiconductor device, for manufacturing the semiconductor device of claim 7, comprising:
providing the substrate;
forming the channel layer, the barrier layer, the barrier modulation layer, a sacrificial material layer, and a doped Group III-V material semiconductor layer stacked in sequence on the substrate; and
etching the doped Group III-V material semiconductor layer and the sacrificial material layer to form the doped Group III-V semiconductor layer and the sacrificial layer, respectively.

20. A manufacturing method of a semiconductor device, for manufacturing the semiconductor device of claim 8, comprising:
providing the substrate;
forming the channel layer, the barrier layer, the barrier modulation layer, a sacrificial material layer, and a doped Group III-V material semiconductor layer stacked in sequence on the substrate; and
etching the doped Group III-V material semiconductor layer and the sacrificial material layer to form the doped Group III-V semiconductor layer and the sacrificial layer, respectively.
